(19) United States
(12) Patent Application Publication
(10) Pub. No.: US 2024/0387695 A1
(43) Pub. Date: Nov. 21, 2024

(54) SEMICONDUCTOR DEVICE AND METHOD FOR FABRICATING THE SAME

(71) Applicant: SK hynix Inc., Gyeonggi-do (KR)

(72) Inventors: Young Gwang YOON, Gyeonggi-do (KR); Yun Ik SON, Gyeonggi-do (KR)

(21) Appl. No.: 18/531,690

(22) Filed: Dec. 7, 2023

(30) Foreign Application Priority Data
May 17, 2023 (KR) 10-2023-0063654

(51) Int. Cl. H01L 29/66; H10B 12/00

(52) U.S. Cl. CPC H01L 29/6656; H01L 29/66545; H10B 12/09; H10B 12/50

(57) ABSTRACT

A semiconductor device includes: a substrate including a peripheral region and a core region; a substrate including a peripheral region and a core region; a first conductive pattern disposed over the substrate of the peripheral region; a second conductive pattern disposed over the substrate of the core region; a first spacer structure formed on both sidewalls of the first conductive pattern; and a second spacer structure having a thickness which is smaller than a total thickness of the first spacer structure formed on both sidewalls of the second conductive pattern.

### CROSS-REFERENCE TO RELATED APPLICATIONS

The present application claims priority of Korean Patent Application No. 10-2023-0063654, filed on May 17, 2023, which is incorporated herein by reference in its entirety.

### BACKGROUND

### 1. Field

Various embodiments of the present invention relate to a method for fabricating a semiconductor device, and more particularly, to spacers that are formed on both sidewalls of a conductive pattern in a core region and a peripheral region, and a method for forming the spacers.

### 2. Description of the Related Art

As core regions shrink due to the high integration of semiconductor devices, the spacing between the conductive patterns that are formed in the core regions decreases as well, and this requires the spacers formed on both sidewalls of the conductive patterns to have the minimized thickness.

Meanwhile, in the peripheral regions, it is necessary to optimize the thickness of the spacers formed on both sidewalls of the conductive patterns in order to improve the performance gain and the short channel effect of a device.

### SUMMARY

Embodiments of the present invention are directed to dualizing the thickness of the spacers formed in a core region and a peripheral region to optimize the thickness of the spacers according to their needs.

In accordance with an embodiment of the present invention, a semiconductor device includes: a substrate including a peripheral region and a core region; a first conductive pattern disposed over the substrate of the peripheral region; a second conductive pattern disposed over the substrate of the core region; a first spacer structure formed on both sidewalls of the first conductive pattern; and a second spacer structure having a thickness which is smaller than a total thickness of the first spacer structure formed on both sidewalls of the second conductive pattern.

In accordance with another embodiment of the present invention, a method for fabricating a semiconductor device includes: providing a substrate including a core region and a peripheral region; forming a first conductive pattern over the peripheral region and a second conductive pattern over the core region; and forming a first spacer structure on both sidewalls of the first conductive pattern and a second spacer structure having different total thicknesses on both sidewalls of the first conductive pattern and the second conductive pattern.

In accordance with another embodiment of the present invention, a method for fabricating a semiconductor device includes: providing a substrate including a core region and a peripheral region; forming a first dummy pattern over the substrate of the peripheral region; forming a second dummy pattern over the substrate of the core region; forming a first spacer structure on both sidewalls of the first dummy patterns and a second spacer structure having a total thickness different from the first spacer structure on both sidewalls of the second dummy pattern; forming an inter-layer dielectric layer that fills a gap between the first dummy pattern and the second dummy pattern; forming recesses in the core region and the peripheral region by removing the first and second dummy patterns; forming an RMG structure by depositing a high-k layer and a conductive material layer in the recesses of the core region and the peripheral region, wherein the first and second spacer structures have different total thicknesses.

### BRIEF DESCRIPTION OF THE DRAWINGS

FIGS. 1 to 4 are cross-sectional views of a semiconductor device including a buffer spacer in accordance with an embodiment of the present invention.

FIGS. 5 to 8 are cross-sectional views of a semiconductor device including an offset spacer in accordance with an embodiment of the present invention.

FIGS. 9 to 12 are cross-sectional views of a semiconductor device including a buffer spacer and a Replacement Metal Gate (RMG) structure in accordance with an embodiment of the present invention.

FIGS. 13 to 16 are cross-sectional views of a semiconductor device including an offset spacer and an RMG structure in accordance with an embodiment of the present invention.

FIGS. 17A to 17E are cross-sectional views illustrating an example of a method for fabricating a semiconductor device including a buffer spacer in accordance with an embodiment of the present invention.

FIGS. 18A to 18F are cross-sectional views illustrating an example of a method for fabricating a semiconductor device including an offset spacer in accordance with an embodiment of the present invention.

FIGS. 19A to 19H are cross-sectional views illustrating an example of a method for fabricating a semiconductor device including an RMG structure in accordance with an embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate. In the present disclosure, the singular forms are intended to include the plural forms as well, unless the context clearly indicates otherwise.

A semiconductor memory device, particularly, a Dynamic Random Access Memory (DRAM) device, typically may include three regions. The first region may be a cell array in which memory cells are arranged in a matrix form, and the second region may be a peripheral circuit region, which is a non-repetitive circuit that stores and transfers data and drives the cell array. Hereinafter, the peripheral circuit region will be referred to as a peripheral region. The third region may be a core region, which is a repetitive circuit including a sense amplifier, a decoder, and the like.

Each of the peripheral region and the core region may include an NMOS region or a PMOS region. A high voltage NMOS transistor and a low voltage NMOS transistor may be formed in the NMOS region of the peripheral region, and a high voltage PMOS transistor and a low voltage PMOS transistor may be formed in the PMOS region of the peripheral region. A high voltage NMOS transistor and a low voltage NMOS transistor may be formed in the NMOS region of the core region, and a high voltage PMOS transistor and a low voltage PMOS transistor may be formed in the PMOS region of the core region.

In the embodiment of the present invention, for the sake of convenience in description, only the peripheral region and the core region are illustrated and described, omitting the cell region. Also, according to the embodiment of the present invention, the NMOS region and the PMOS region, an NMOS transistor and a PMOS transistor, and a high voltage transistor and a low voltage transistor in the peripheral region and the core region are not separately described, but the embodiment of the present invention may be applied according to the type and transistor in each region.

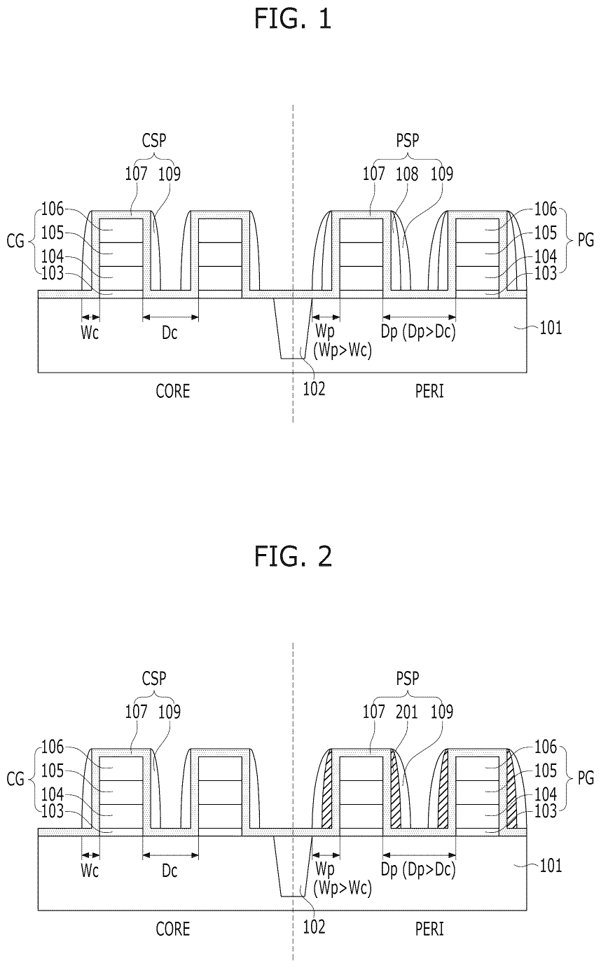

FIGS. 1 to 4 are cross-sectional views of a semiconductor device including a buffer spacer in accordance with an embodiment of the present invention. The constituent elements of FIGS. 1 to 4 may be the same except for the stacked structure and material of the buffer spacer. Therefore, in FIGS. 2 to 4, the description on the same constituent elements also appearing in FIG. 1 will be omitted or simplified.

Referring to FIG. 1, a substrate 101 may include a peripheral region PERI and a core region CORE.

The substrate 101 may be a material suitable for semiconductor processing. The substrate 101 may include a semiconductor substrate. The substrate 101 may be formed of a silicon-containing material. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include other semiconductor materials, such as germanium. The substrate 101 may include a III/V-group semiconductor substrate, for example, a compound semiconductor substrate, such as GaAs. The substrate 101 may include a Silicon-On-Insulator (SOI) substrate.

In the substrate 101, the isolation layer 102 may divide the substrate 101 into the peripheral region PERI and the core region CORE and define an active region.

A peripheral conductive pattern PG may be formed over the substrate 101 of the peripheral region PERI. A core conductive pattern CG may be formed over the substrate 101 of the core region CORE. A bit line structure or a gate structure disposed at the same level as the peripheral conductive pattern PG of the peripheral region PERI and the core conductive pattern CG of the core region CORE may be formed in the cell region.

The line widths of the peripheral conductive pattern PG and the core conductive pattern CG may be the same. According to another embodiment of the present invention, the line widths of the peripheral conductive pattern PG and the core conductive pattern CG may be different. As the core region adjacent to the cell region is reduced due to the miniaturization of semiconductor devices, the distance Dp between the peripheral conductive patterns PG may be longer than the distance Dc between the core conductive patterns CG (Dp>Dc).

The peripheral conductive pattern PG and the core conductive pattern CG may include a planar gate pattern. The peripheral conductive pattern PG and the core conductive pattern CG may include a stacked structure of the same materials. In other words, the peripheral conductive pattern PG and the core conductive pattern CG may be simultaneously formed by sequentially stacking the same material layers and patterning them once. Each of the peripheral conductive patterns PG and the core conductive pattern CG may be formed as a stacked structure of a gate dielectric layer 103, a first gate electrode 104, a second gate electrode 105, and a gate hard mask 106 stacked in the recited order over the substrate 101 in the peripheral region PERI and core region CORE, respectively.

A peripheral spacer structure PSP may be formed on both sidewalls of the peripheral conductive pattern PG, and a core spacer structure CSP may be formed on both sidewalls of the core conductive pattern CG. A part of the peripheral spacer structure PSP may be formed also over a top surface of the peripheral conductive pattern PG. A part of the core spacer structure CSP may be formed also over a top surface of the core conductive pattern CG. The total thickness Wp of the peripheral spacer structure PSP may be greater than the total thickness Wc of the core spacer structure CSP (Wp>Wc).

The gate dielectric layer 103 may include a dielectric material. For example, the gate dielectric layer 103 may include silicon oxide. According to another embodiment of the present invention, the gate dielectric layer 103 may include a high-k material.

The first gate electrode 104 and the second gate electrode 105 may include a conductive material. The first gate electrode 104 may include a semiconductor material. For example, the first gate electrode 104 may include polysilicon, but the concept and scope of the present invention are not limited thereto. The second gate electrode 105 may include a metal material. For example, the gate electrode 105 may include tungsten or a tungsten-containing material, but the concept and scope of the present invention are not limited thereto.

The gate hard mask 106 may include a dielectric material. The gate hard mask 106 may be provided to protect the upper surface of the second gate electrode 105 and to pattern the gate dielectric layer 103, the first gate electrode 104, and the second gate electrode 105, and the gate hard mask 106 may be formed of a material having an etch selectivity with respect to the gate dielectric layer 103, the first gate electrode 104 and the second gate electrode 105. For example, the gate hard mask 106 may include silicon nitride.

The peripheral spacer structure PSP and the core spacer structure CSP may include different stacked structures. The peripheral spacer structure PSP may include at least one more layer of a spacer material than the core spacer structure CSP.

The peripheral spacer structure PSP may include a stacked structure of a nitride spacer 107, a first oxide spacer 108, and a second oxide spacer 109. The nitride spacer 107 may be formed also over the top surface of the peripheral conductive pattern PG.

The core spacer structure CSP may include a stacked structure of a nitride spacer 107 and a second oxide spacer 109. The nitride spacer 107 may be formed also over the top surface of the core conductive pattern CG.

Referring to FIG. 2, the peripheral spacer structure PSP may include a stacked structure of a nitride spacer 107, a low-k spacer 201, and a second oxide spacer 109. For example, the low-k spacer 201 may include one selected from the group including SiBN (silicon boron nitride), SiBCN (silicon boron carbon nitride), SiCO (silicon carbon oxide), and SiCON (silicon carbon oxynitride).

The core spacer structure CSP may include a stacked structure of a nitride spacer 107 and an oxide spacer 109.

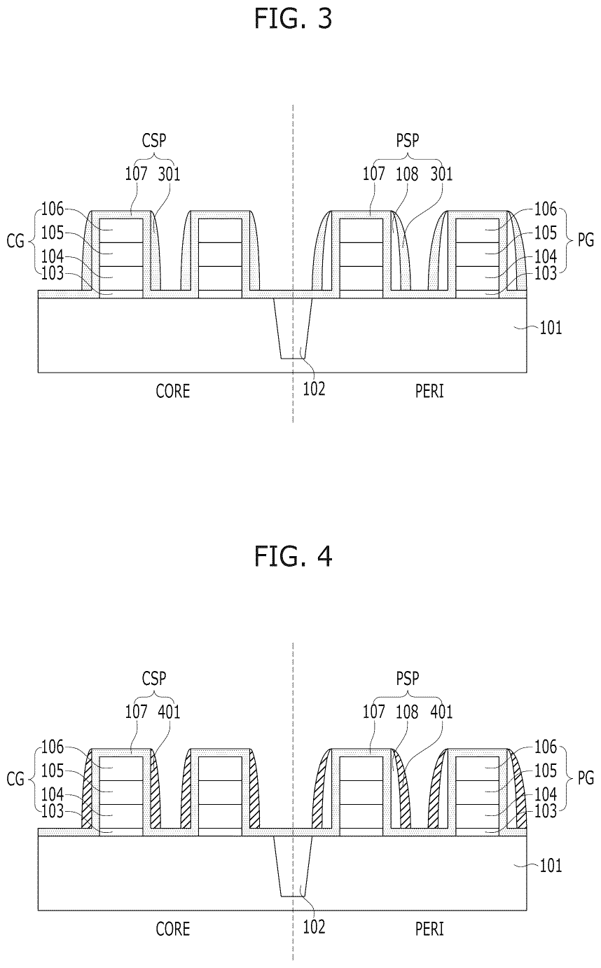

Referring to FIG. 3, the peripheral spacer structure PSP may include a stacked structure of a first nitride spacer 107, an oxide spacer 108, and a second nitride spacer 301.

The core spacer structure CSP may include a stacked structure of a first nitride spacer 107 and a second nitride spacer 301.

Referring to FIG. 4, the peripheral spacer structure PSP may include a stacked structure of a nitride spacer 107, an oxide spacer 108, and a low-k spacer 401.

The core spacer structure CSP may include a stacked structure of a nitride spacer 107 and a low-k spacer 401. For example, the low-k spacer 401 may include one selected from the group including SiBN, SiBCN, SiCO, and SiCON.

Referring to FIGS. 1 to 4 described above, according to the embodiment of the present invention, the first nitride spacer 107 in the peripheral spacer structure PSP and the core spacer structure CSP may be a continuous buffer spacer that covers the upper portion of the substrate 101 between the conductive patterns as well as the sidewalls of each conductive patterns.

Also, it is possible to secure reliability of the semiconductor device by dualizing the spacer thickness of the peripheral spacer structure PSP and the spacer thickness of the core spacer structure CSP and applying the spacer thickness optimized for each region. In particular, mismatch of a sense amplifier transistor based on the variation of ion implantation may be reduced by forming the total thickness Wp of the peripheral spacer structure PSP.

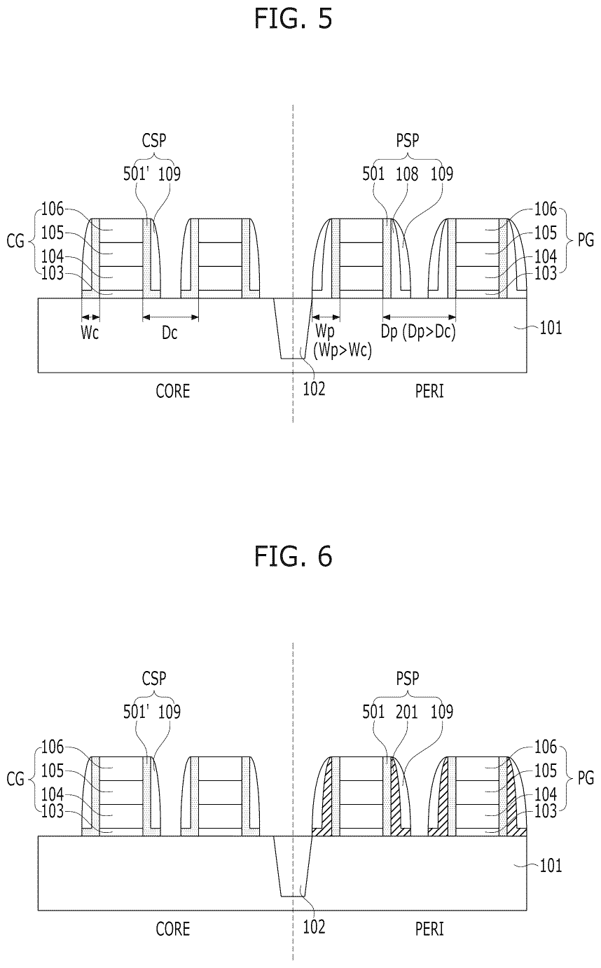

FIGS. 5 to 8 are cross-sectional views of a semiconductor device including an offset spacer in accordance with an embodiment of the present invention. All the constituent elements of FIGS. 5 to 8 may be the same, except for the stacked structure and material of the offset spacer. Therefore, in FIGS. 6 to 8, the description on the same constituent elements also appearing in FIG. 5 will be omitted or simplified.

Referring to FIG. 5, the substrate 101 may include a peripheral region PERI and a core region CORE.

The substrate 101 may be a material suitable for semiconductor processing. The substrate 101 may include a semiconductor substrate. The substrate 101 may be formed of a silicon-containing material. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include other semiconductor materials, such as germanium. The substrate 101 may include a III/V-group semiconductor substrate, for example, a compound semiconductor substrate, such as GaAs. The substrate 101 may include a Silicon-On-Insulator (SOI) substrate.

In the substrate 101, the isolation layer 102 may divide the substrate 101 into the peripheral region PERI and the core region CORE and define an active region.

A peripheral conductive pattern PG may be formed over the substrate 101 of the peripheral region PERI. A core conductive pattern CG may be formed over the substrate 101 of the core region CORE. A bit line structure or a gate structure disposed at the same level as the peripheral conductive pattern PG of the peripheral region PERI and the core conductive pattern CG of the core region CORE may be formed in the cell region.

The line widths of the peripheral conductive pattern PG and the core conductive pattern CG may be the same. As the core region adjacent to the cell region is reduced due to the miniaturization of semiconductor devices, the distance Dp between the peripheral conductive patterns PG may be longer than the distance Dc between the core conductive patterns CG (Dp>Dc).

The peripheral conductive pattern PG and the core conductive pattern CG may include a stacked structure of the same materials. In other words, the peripheral conductive pattern PG and the core conductive pattern CG may be simultaneously formed by sequentially stacking the same material layers and patterning them once. The peripheral conductive pattern PG and the core conductive pattern CG may be formed as a stacked structure of a gate dielectric layer 103, a first gate electrode 104, a second gate electrode 105, and a gate hard mask 106 stacked in the recited order over the substrate 101 in the peripheral region PERI and core region CORE, respectively.

A peripheral spacer structure PSP may be formed on both sidewalls of the peripheral conductive pattern PG, and a core spacer structure CSP may be formed on both sidewalls of the core conductive pattern CG. The total thickness Wp of the peripheral spacer structure PSP may be greater than the total thickness Wc of the core spacer structure CSP (Wp>Wc).

The gate dielectric layer 103 may include a dielectric material. For example, the gate dielectric layer 103 may include silicon oxide. According to another embodiment of the present invention, the gate dielectric layer 103 may include a high-k material.

The first gate electrode 104 and the second gate electrode 105 may include a conductive material. The first gate electrode 104 may include a semiconductor material. For example, the first gate electrode 104 may include polysilicon, but the concept and scope of the present invention are not limited thereto. The second gate electrode 105 may include a metal material. For example, the gate electrode 105 may include tungsten or a tungsten-containing material, but the concept and scope of the present invention are not limited thereto.

The gate hard mask 106 may include a dielectric material. The gate hard mask 106 may be provided to protect the upper surface of the second gate electrode 105 and to pattern the gate dielectric layer 103, the first gate electrode 104, and the second gate electrode 105, and the gate hard mask 106 may be formed of a material having an etch selectivity with respect to the gate dielectric layer 103, the first gate electrode 104 and the second gate electrode 105. For example, the gate hard mask 106 may include silicon nitride.

The peripheral spacer structure PSP and the core spacer structure CSP may include different stacked structures. The peripheral spacer structure PSP may include at least one more layer of a spacer material than the core spacer structure CSP.

The peripheral spacer structure PSP may include a stacked structure of a nitride spacer 501, a first oxide spacer 108, and a second oxide spacer 109.

The core spacer structure CSP may include a stacked structure of a nitride spacer 501′ and a second oxide spacer 109.

Referring to FIG. 6, the peripheral spacer structure PSP may include a stacked structure of a nitride spacer 501, a low-k spacer 201, and an oxide spacer 109. For example, the low-k spacer 201 may include one selected from the group including SiBN, SiBCN, SiCO, and SiCON.

The core spacer structure CSP may include a stacked structure of a nitride spacer 501′ and an oxide spacer 109.

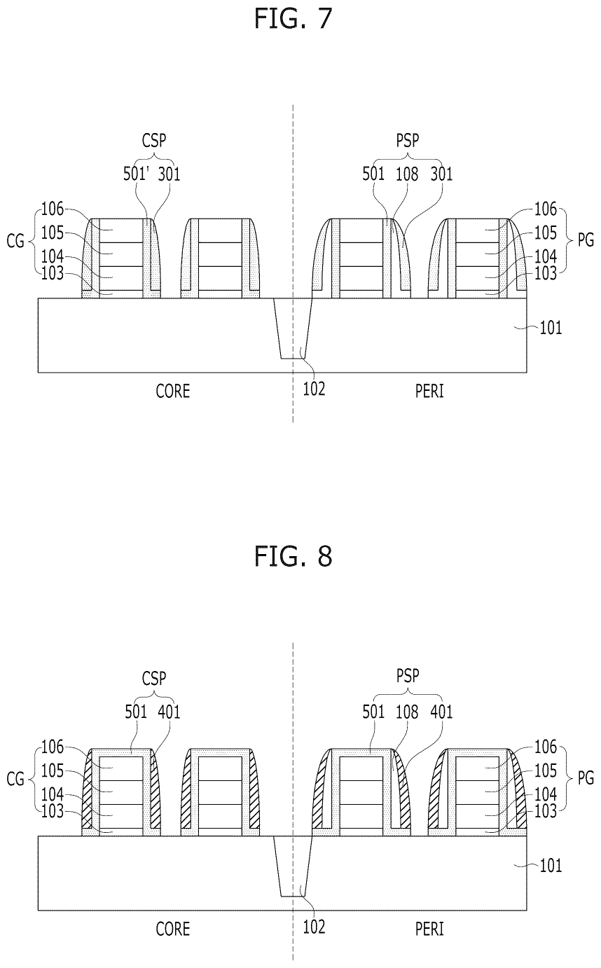

Referring to FIG. 7, the peripheral spacer structure PSP may include a stacked structure of a first nitride spacer 501, an oxide spacer 108, and a second nitride spacer 301.

The core spacer structure CSP may include a stacked structure of a first nitride spacer 501′ and a second nitride spacer 301.

Referring to FIG. 8, the peripheral spacer structure PSP may include a stacked structure of a nitride spacer 501, an oxide spacer 108, and a low-k spacer 401.

The core spacer structure CSP may include a stacked structure of a nitride spacer 501′ and a low-k spacer 401. For example, the low-k spacer 401 may include one selected from the group including SiBN, SiBCN, SiCO, and SiCON.

Referring to FIGS. 5 to 8, according to the embodiment of the present invention, the nitride spacer 501 of the peripheral spacer structure PSP may be an offset spacer disposed only on both sidewalls of the peripheral conductive pattern PG. Accordingly, since a dopant may be directly implanted into the substrate 101 during an ion implantation for junction, it may be advantageous for junction engineering. In the core spacer structure CSP, the nitride spacer 501′ may be a buffer spacer that covers a portion of the substrate 101 between the conductive patterns as well as both sidewalls of each conductive pattern.

Also, reliability of the semiconductor device may be secured by dualizing the spacer thickness of the peripheral spacer structure PSP and the spacer thickness of the core spacer structure CSP and applying the spacer thickness optimized for each region. In particular, mismatch of a sense amplifier transistor based on the variation of an ion implantation may be improved by forming the total thickness Wp of the peripheral spacer structure PSP.

According to another embodiment of the present invention, just as the peripheral spacer structure PSP, the core spacer structure CSP may use the nitride spacer 501′ also as the offset spacers disposed only on both sidewalls of the core conductive pattern CG.

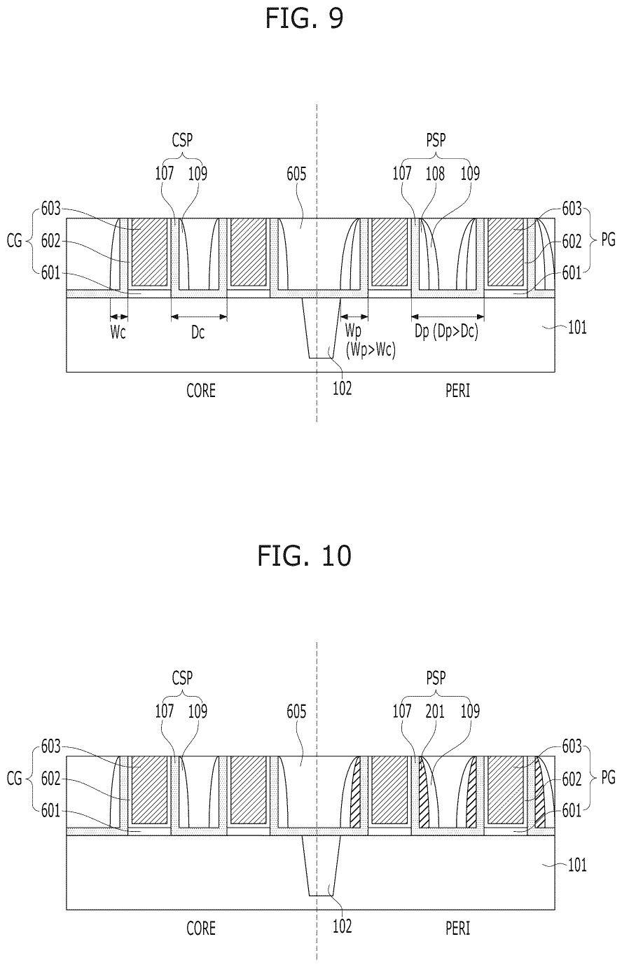

FIGS. 9 to 12 are cross-sectional views of a semiconductor device including a buffer spacer and a Replacement Metal Gate (RMG) structure in accordance with an embodiment of the present invention. All the constituent elements of FIGS. 9 to 12 may be the same as those of FIGS. 1 to 4, except for the stacked structure of the conductive patterns. Therefore, in FIGS. 9 to 12, the description on the same constituent elements also appearing in FIGS. 1 to 4 will be omitted or simplified.

Referring to FIG. 9, the substrate 101 may include a peripheral region and a core region.

The substrate 101 may be a material suitable for semiconductor processing. The substrate 101 may include a semiconductor substrate. The substrate 101 may be formed of a silicon-containing material. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include other semiconductor materials, such as germanium. The substrate 101 may include a III/V-group semiconductor substrate, for example, a compound semiconductor substrate, such as GaAs. The substrate 101 may include a Silicon-On-Insulator (SOI) substrate.

In the substrate 101, the isolation layer 102 may divide the substrate 101 into the peripheral region PERI and the core region CORE and define an active region.

A peripheral conductive pattern PG may be formed over the substrate 101 in the peripheral region PERI. A core conductive pattern CG may be formed over the substrate 101 in the core region CORE. The peripheral conductive pattern PG and the core conductive pattern CG may include a replacement metal gate (RMG) structure. An inter-layer dielectric layer 605 may gap-fill the space between the peripheral conductive pattern PG and the core conductive pattern CG. A bit line structure or a gate structure disposed at the same level as the peripheral conductive pattern and the core conductive pattern of the peripheral region PERI and the core region CORE may be formed in the cell region.

The line widths of the peripheral conductive pattern PG and the core conductive pattern CG may be different or the same. For example, in an embodiment, as the core region adjacent to the cell region may be reduced for increasing the miniaturization of the semiconductor device, and the distance Dp between the peripheral conductive patterns PG may be longer than the distance Dc between the core conductive patterns CG (Dp>Dc).

The peripheral conductive pattern PG and the core conductive pattern CG may include a replacement metal gate (RMG) structure. The RMG structures in the peripheral conductive pattern PG and the core conductive pattern CG may include a stacked structure of the same materials. The peripheral conductive pattern PG and the core conductive pattern CG may be formed as a stacked structure of a gate dielectric layer 601, a high-k layer 602, and a gate electrode 603 stacked in the recited order over the substrate 101 in the peripheral region PERI and core region CORE, respectively. The dielectric layer 601 may have a line-shape, the high-k layer 602 may have a U-shape, and the gate electrode 603 may have a pillar shape filling the space within the U-shape high k layer 602. The high-k layer 602 may have a flat bottom formed on the dielectric layer 601 and vertical sidewalls.

A peripheral spacer structure PSP may be formed on both sidewalls of the peripheral conductive pattern PG, and a core spacer structure CSP may be formed on both sidewalls of the core conductive pattern CG. The total thickness Wp of the peripheral spacer structure PSP may be greater than the total thickness Wc of the core spacer structure CSP (Wp>Wc).

The gate dielectric layer 601 may include a dielectric material. For example, the gate dielectric layer 601 may include silicon oxide.

The high-k layer 602 may include a high-k material having a higher dielectric constant than silicon oxide. For example, the high-k layer 602 may include at least one among boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The gate electrode 603 may include at least one among a metal, a metal alloy, a conductive metal nitride, a metal silicide, a doped semiconductor material, a conductive metal oxide, and a conductive metal oxynitride. The gate electrode 603 may include at least one among, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but the concept and scope of the present invention are not limited thereto. The conductive metal oxide and conductive metal oxynitride may include an oxidized form of the above-described material, but the concept and scope of the present invention are not limited thereto.

The inter-layer dielectric layer 605 may include a dielectric material. The inter-layer dielectric layer 605 may include, for example, one selected among silicon oxide, silicon nitride, and silicon oxynitride.

The peripheral spacer structure PSP may include a stacked structure of a nitride spacer 107, a first oxide spacer 108, and a second oxide spacer 109.

The core spacer structure CSP may include a stacked structure of a nitride spacer 107 and a second oxide spacer 109.

Referring to FIG. 10, the peripheral spacer structure PSP may include a stacked structure of a nitride spacer 107, a low-k spacer 201, and a second oxide spacer 109. For example, the low-k spacer 201 may include one selected from the group including SiBN, SiBCN, SiCO, and SiCON.

The core spacer structure CSP may include a stacked structure of a nitride spacer 107 and an oxide spacer 109.

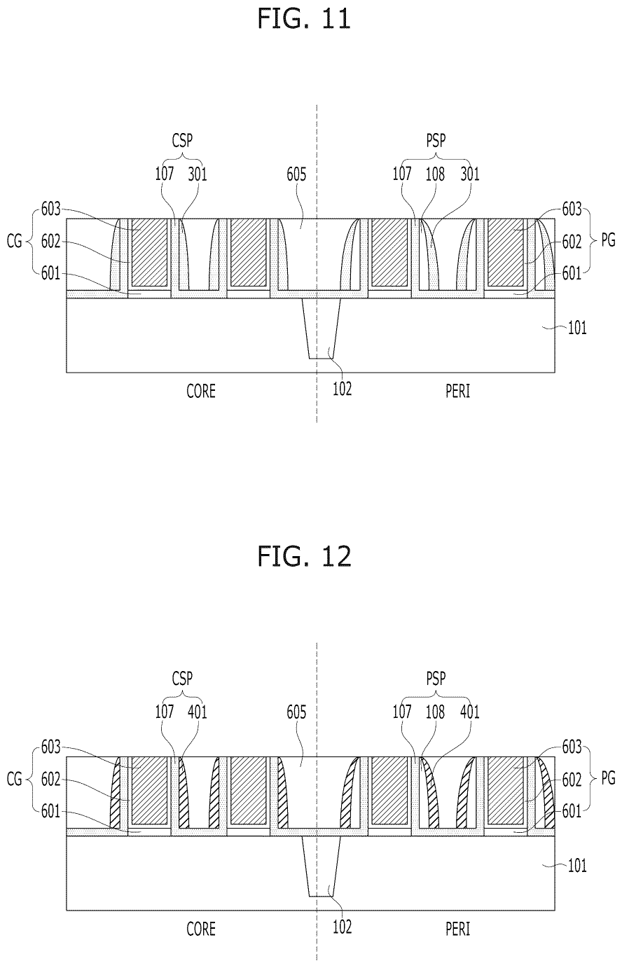

Referring to FIG. 11, the peripheral spacer structure PSP may include a stacked structure of a first nitride spacer 107, an oxide spacer 108, and a second nitride spacer 301.

The core spacer structure CSP may include a stacked structure of a first nitride spacer 107 and a second nitride spacer 301.

Referring to FIG. 12, the peripheral spacer structure PSP may include a stacked structure of a nitride spacer 107, an oxide spacer 108, and a low-k spacer 401.

The core spacer structure CSP may include a stacked structure of a nitride spacer 107 and a low-k spacer 401. For example, the low-k spacer 401 may include one selected from the group including SiBN, SiBCN, SiCO, and SiCON.

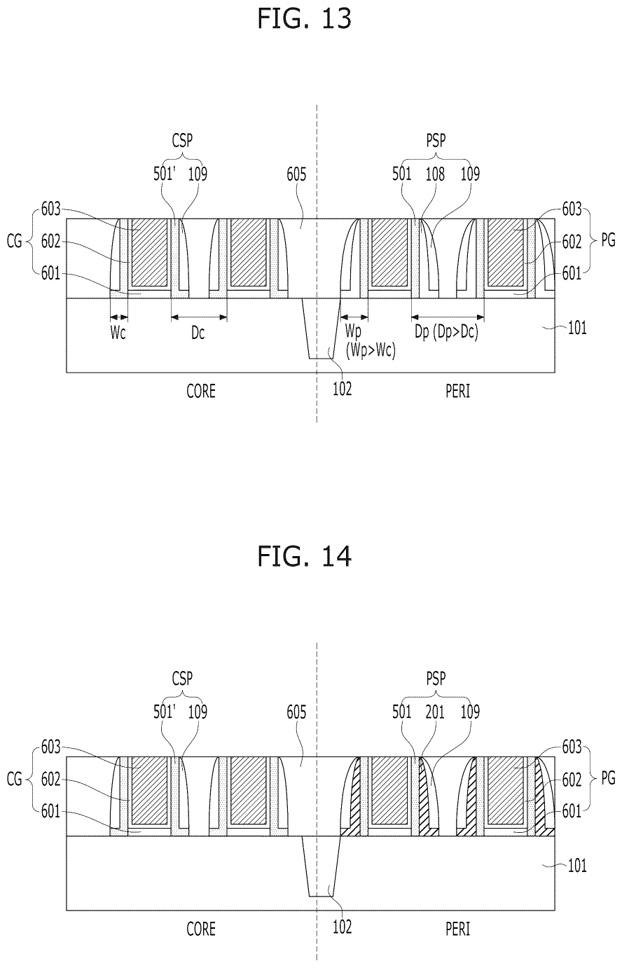

FIGS. 13 to 16 are cross-sectional views of a semiconductor device including an offset spacer and an RMG structure in accordance with an embodiment of the present invention. All the constituent elements of FIGS. 13 to 16 may be the same as those of FIGS. 5 to 8 except for the stacked structure of the conductive patterns. Therefore, description on the same constituent elements also appearing in FIGS. 13 to 16 will be omitted or simplified.

Referring to FIG. 13, the peripheral conductive pattern PG and the core conductive pattern CG may include a replacement metal gate (RMG) structure. The RMG structures in the peripheral conductive pattern PG and the core conductive pattern CG may include a stacked structure of the same materials. The peripheral conductive pattern PG and the core conductive pattern CG may be formed as a stacked structure of a gate dielectric layer 601, a high-k layer 602, and a gate electrode 603 stacked in the recited order over the substrate 101 in the peripheral region PERI and core region CORE, respectively.

A peripheral spacer structure PSP may be formed on both sidewalls of the peripheral conductive pattern PG, and a core spacer structure CSP may be formed on both sidewalls of the core conductive pattern CG. The total thickness Wp of the peripheral spacer structure PSP may be greater than the total thickness Wc of the core spacer structure CSP (Wp>Wc).

The gate dielectric layer 601 may include a dielectric material. For example, the gate dielectric layer 601 may include silicon oxide.

The high-k layer 602 may include a high-k material having a higher dielectric constant than silicon oxide. For example, the high-k layer 602 may include at least one among boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate electrode 603 may include at least one among a metal, a metal alloy, a conductive metal nitride, a metal silicide, a doped semiconductor material, a conductive metal oxide, and a conductive metal oxynitride. The gate electrode 603 may include at least one among, for example, titanium nitride (TIN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MON), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but the concept and scope of the present invention are not limited thereto. The conductive metal oxide and conductive metal oxynitride may include an oxidized form of the above-described material, but the concept and scope of the present invention are not limited thereto.

The peripheral spacer structure PSP may include a stacked structure of a nitride spacer 501, a first oxide spacer 108, and a second oxide spacer 109.

The core spacer structure CSP may include a stacked structure of a nitride spacer 501′ and a second oxide spacer 109.

Referring to FIG. 14, the peripheral spacer structure PSP may include a stacked structure of a nitride spacer 501, a low-k spacer 201, and an oxide spacer 109. For example, the low-k spacer 201 may include one selected from the group including SiBN, SiBCN, SiCO, and SiCON.

The core spacer structure CSP may include a stacked structure of a nitride spacer 501′ and an oxide spacer 109.

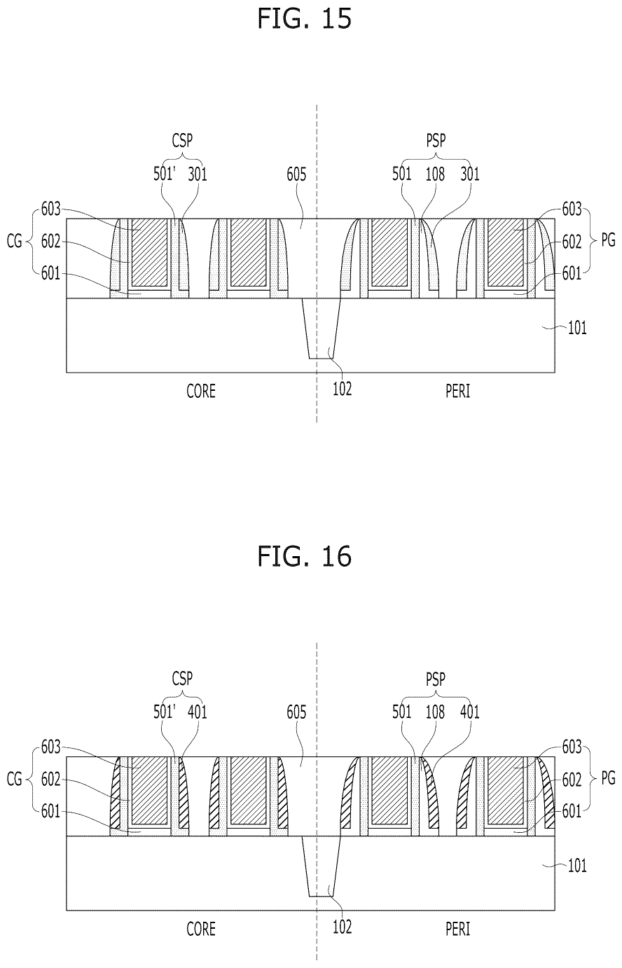

Referring to FIG. 15, the peripheral spacer structure PSP may include a stacked structure of a first nitride spacer 501, an oxide spacer 108, and a second nitride spacer 301.

The core spacer structure CSP may include a stacked structure of a first nitride spacer 501′ and a second nitride spacer 301.

In particular, according to the embodiment of the present invention, the nitride spacer 501 of the peripheral spacer structure PSP may be an offset spacer disposed only on both sidewalls of the peripheral conductive pattern PG. Also, in the core spacer structure CSP, the nitride spacer 501′ may be a buffer spacer that covers not only both sidewalls of each conductive pattern, but also a portion of the substrate 101 between the conductive patterns.

Referring to FIG. 16, the peripheral spacer structure PSP may include a stacked structure of a nitride spacer 501, an oxide spacer 108, and a low-k spacer 401.

The core spacer structure CSP may include a stacked structure of a nitride spacer 501′ and a low-k spacer 401. For example, the low-k spacer 401 may include one selected from the group including SiBN, SiBCN, SiCO, and SiCON.

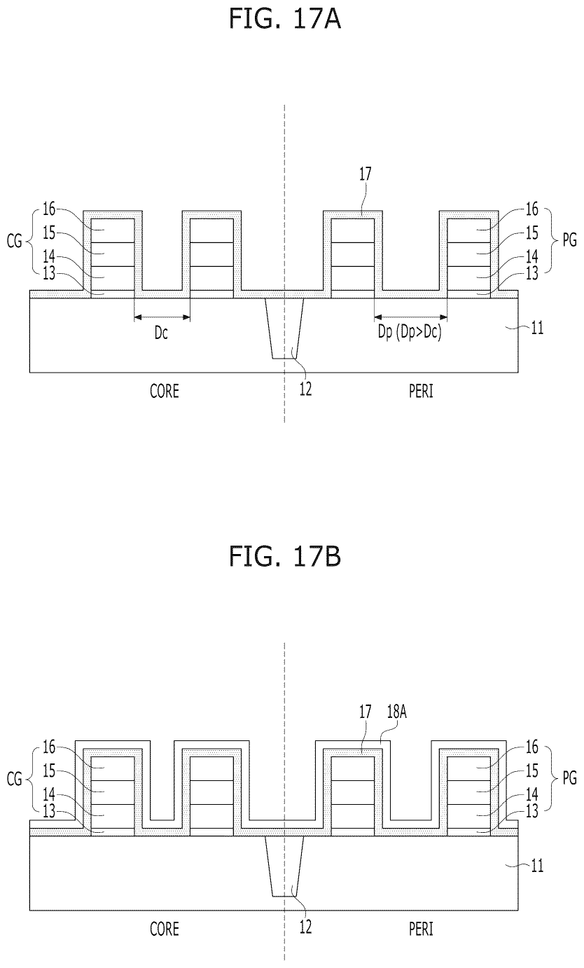

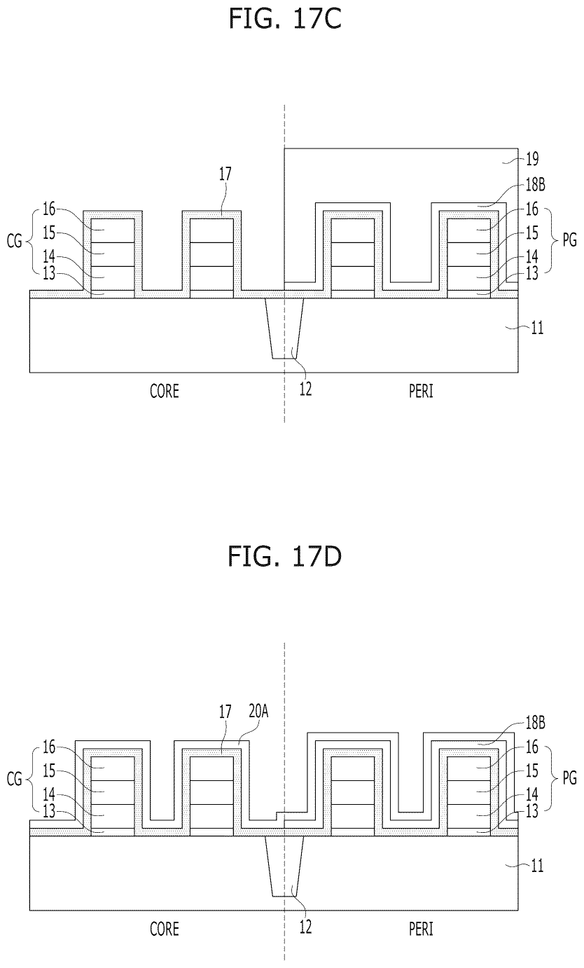

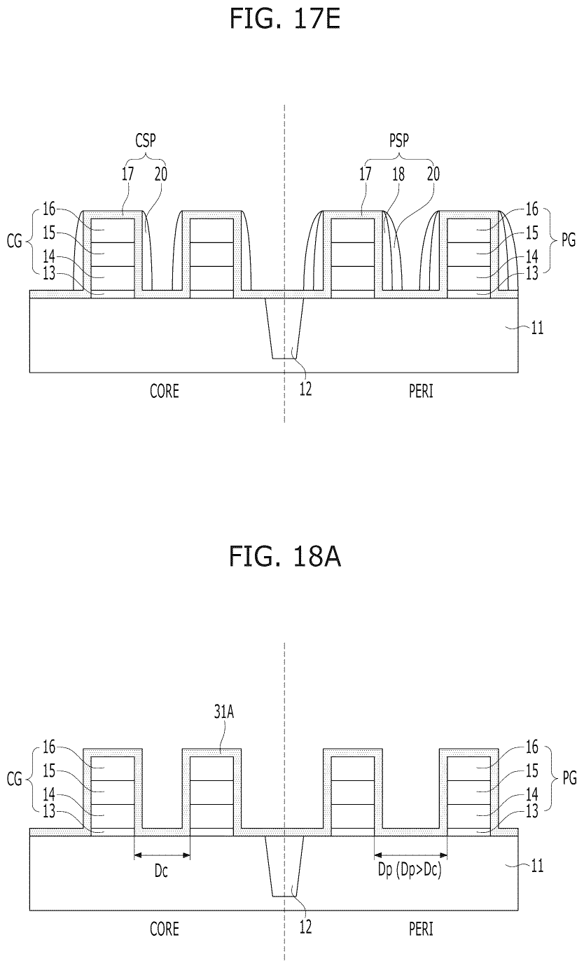

FIGS. 17A to 17E are cross-sectional views illustrating an example of a method for fabricating a semiconductor device including a buffer spacer in accordance with an embodiment of the present invention. FIGS. 17A to 17E describe a method for fabricating the semiconductor device shown in FIG. 1, and the process may be the same as the method for fabricating the semiconductor device illustrated in FIGS. 2 to 4, except for the type of the spacer material.

Referring to FIG. 17A, in the substrate 11, the isolation layer 12 may divide the substrate 11 into the peripheral region PERI and the core region CORE and define an active region.

The substrate 11 may be a material suitable for semiconductor processing. The substrate 11 may include a semiconductor substrate. The substrate 11 may be formed of a silicon-containing material. The substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may also include other semiconductor materials, such as germanium. The substrate 11 may include a III/V-group semiconductor substrate, for example, a compound semiconductor substrate, such as GaAs. The substrate 101 may include a Silicon-On-Insulator (SOI) substrate.

Subsequently, a peripheral conductive pattern PG and a core conductive pattern CG may be formed over the substrate in the peripheral region PERI and the core region CORE, respectively. The peripheral conductive pattern PG and the core conductive pattern CG may have the same stacked structure.

The line widths of the peripheral conductive pattern PG and the core conductive pattern CG may be different or the same. For example, in an embodiment, as the core region adjacent to the cell region is reduced due to the miniaturization of the semiconductor devices, the distance Dp between the peripheral conductive patterns PG may be longer than the distance Dc between the core conductive patterns CG (Dp>Dc).

The peripheral conductive pattern PG and the core conductive pattern CG may include a stacked structure of the same materials. In other words, the peripheral conductive pattern PG and the core conductive pattern CG may be simultaneously formed by sequentially stacking the same material layers and patterning them once. The peripheral conductive pattern PG and the core conductive pattern CG may be formed as a stacked structure of a gate dielectric layer 13, a first gate electrode 14, a second gate electrode 15, and a gate hard mask 16 stacked in the recited order over the substrate 101 in the peripheral region PERI and core region CORE, respectively.

The gate dielectric layer 13 may include a dielectric material. For example, the gate dielectric layer 13 may include silicon oxide. According to another embodiment of the present invention, the gate dielectric layer 13 may include a high-k material.

The first gate electrode 14 and the second gate electrode 15 may include a conductive material. The first gate electrode 14 may include a semiconductor material. For example, the first gate electrode 14 may include polysilicon, but the concept and scope of the present invention are not limited thereto. The second gate electrode 15 may include a metal material. For example, the gate electrode 15 may include tungsten or a tungsten-containing material, but the concept and scope of the present invention are not limited thereto.

The gate hard mask 16 may include a dielectric material. The gate hard mask 16 may be provided to protect the upper surface of the second gate electrode 15 and to pattern the gate dielectric layer 13, the first gate electrode 14, and the second gate electrode 15. The gate hard mask 16 may be formed of a material having an etch selectivity with respect to the gate dielectric layer 13, the first gate electrode 14 and the second gate electrode 15. For example, the gate hard mask 16 may include silicon nitride.

Subsequently, a nitride layer 17 may be formed along the profile of the entire structure including the peripheral conductive pattern PG and the core conductive pattern CG.

Referring to FIG. 17B, a first oxide layer 18A may be formed over the nitride layer 17.

Referring to FIG. 17C, a core open mask 19 may be formed over the first oxide layer 18A (refer to FIG. 17B) of the peripheral region PERI. The core open mask 19 may be formed of, for example, a photoresist.

Subsequently, the first oxide layer 18A (see FIG. 17B) of the core region CORE may be removed. Accordingly, the first oxide layer 18B may remain only in the peripheral region PERI.

Referring to FIG. 17D, a second oxide layer 20A may be formed over the nitride layer 17 of the core region CORE and the first oxide layer 18B of the peripheral region PERI.

Referring to FIG. 17E, spacer etching may be performed. As a result of the spacer etching, a peripheral spacer structure PSP where a buffer nitride spacer 17, a first oxide spacer 18, and a second oxide spacer 20 are stacked may be formed on both sidewalls of the peripheral conductive pattern PG. Also, a core spacer structure CSP where the buffer nitride spacer 17 and the second oxide spacer 20 are stacked may be formed on both sidewalls of the core conductive pattern CG.

As described above, according to the embodiment of the present invention, spacer materials having an etch selectivity may be applied to form the spacer structures optimized for the requirements of the peripheral region PERI and the core region CORE, individually. In particular, mismatch of a sense amplifier transistor based on the variation of ion implantation may be reduced by forming the total thickness of the core spacer structure CSP smaller than the total thickness Wp of the peripheral spacer structure PSP.

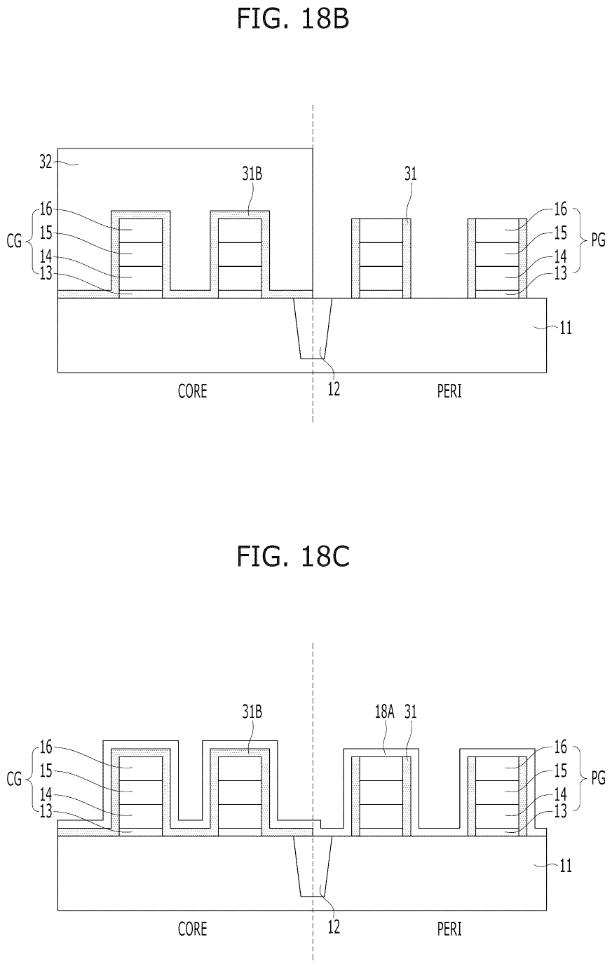

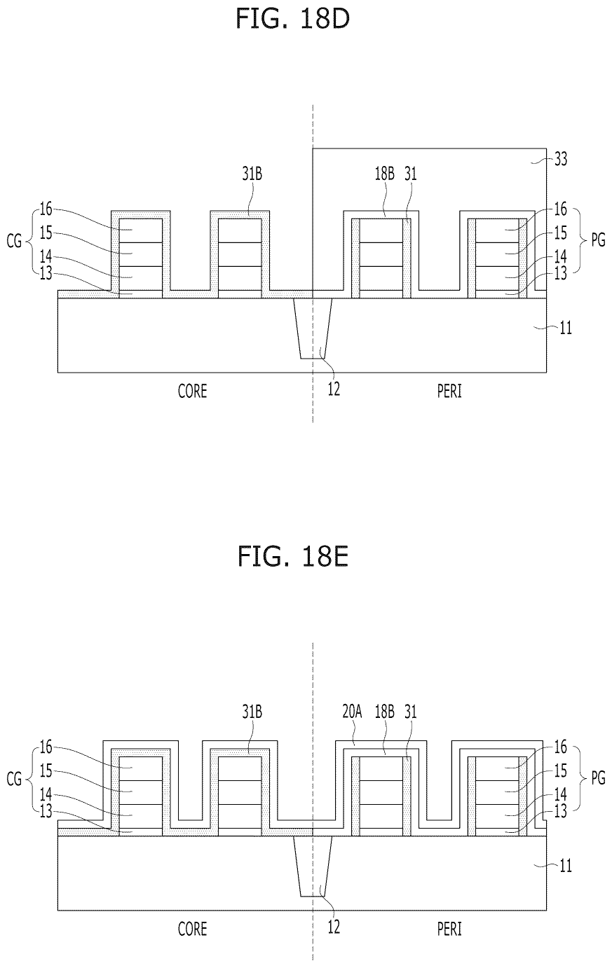

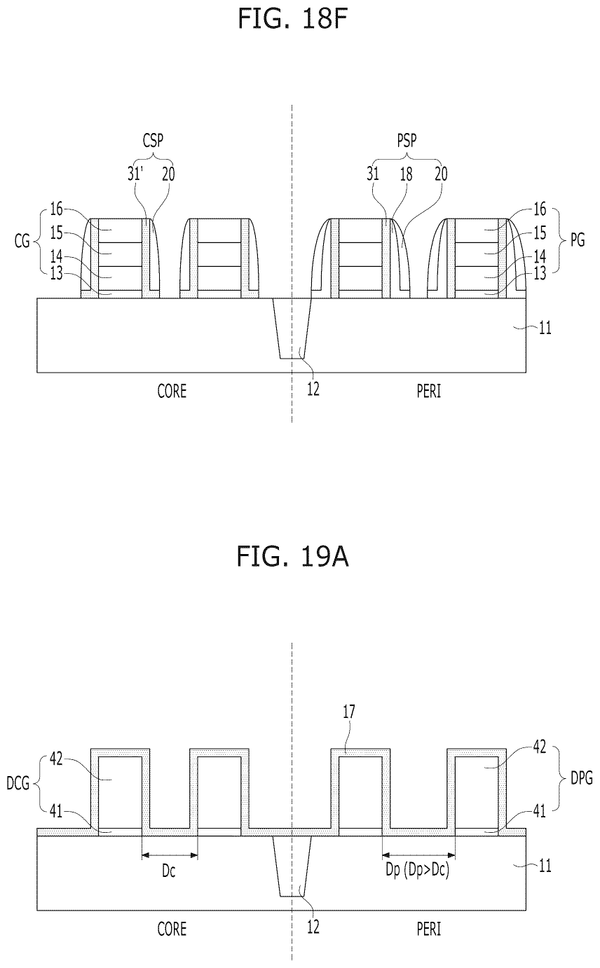

FIGS. 18A to 18F are cross-sectional views illustrating an example of a method for fabricating a semiconductor device including an offset spacer in accordance with an embodiment of the present invention. FIGS. 18A to 18E describe a method for fabricating the semiconductor device shown in FIG. 5, and the process may be the same as the method for fabricating the semiconductor device illustrated in FIGS. 6 to 8, except for the type of the spacer material.

Referring to FIG. 18A, in the substrate 11, the isolation layer 12 may divide the substrate 11 into the peripheral region PERI and the core region CORE and define an active region.

The substrate 11 may be a material suitable for semiconductor processing. The substrate 11 may include a semiconductor substrate. The substrate 11 may be formed of a silicon-containing material. The substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may also include other semiconductor materials, such as germanium. The substrate 11 may include a III/V-group semiconductor substrate, for example, a compound semiconductor substrate, such as GaAs. The substrate 101 may include a Silicon-On-Insulator (SOI) substrate.

Subsequently, a peripheral conductive pattern PG and a core conductive pattern CG may be formed over the substrate in the peripheral region PERI and the core region CORE, respectively. The peripheral conductive pattern PG and the core conductive pattern CG may have the same stacked structure.

The line widths of the peripheral conductive pattern PG and the core conductive pattern CG may be different or the same. For example, in an embodiment, as the core region adjacent to the cell region is reduced due to the miniaturization of the semiconductor devices, the distance Dp between the peripheral conductive patterns PG may be longer than the distance Dc between the core conductive patterns CG (Dp>Dc).

The peripheral conductive pattern PG and the core conductive pattern CG may include a stacked structure of the same materials. In other words, the peripheral conductive pattern PG and the core conductive pattern CG may be simultaneously formed by sequentially stacking the same material layers and patterning them once. The peripheral conductive pattern PG and the core conductive pattern CG may be formed as a stacked structure of a gate dielectric layer 13, a first gate electrode 14, a second gate electrode 15, and a gate hard mask 16 stacked in the recited order over the substrate 101 in the peripheral region PERI and core region CORE, respectively.

The gate dielectric layer 13 may include a dielectric material. For example, the gate dielectric layer 13 may include silicon oxide. According to another embodiment of the present invention, the gate dielectric layer 13 may include a high-k material.

The first gate electrode 14 and the second gate electrode 15 may include a conductive material. The first gate electrode 14 may include, for example, a semiconductor material such as polysilicon. The second gate electrode 15 may include, for example, a metal material such as tungsten or a tungsten-containing material. However, the present invention is not limited thereto. The second gate electrode 15 may include other conductive materials such as cobalt or ruthenium.

The gate hard mask 16 may include a dielectric material. The gate hard mask 16 may be provided to protect the upper surface of the second gate electrode 15 and to pattern the gate dielectric layer 13, the first gate electrode 14, and the second gate electrode 15, and the gate hard mask 16 may be formed of a material having an etch selectivity with respect to the gate dielectric layer 13, the first gate electrode 14 and the second gate electrode 15. For example, the gate hard mask 16 may include silicon nitride.

Subsequently, a nitride layer 31A may be formed along the profile of the entire structure including the peripheral conductive pattern PG and the core conductive pattern CG.

Referring to FIG. 18B, a peripheral open mask 32 opening the peripheral region PERI may be formed over the nitride layer 31A (see FIG. 18A) of the core region CORE. The peripheral open mask 32 may be formed of, for example, a photoresist.

Subsequently, spacer etching may be performed to form offset nitride spacers 31 on both sidewalls of the peripheral conductive pattern PG. The substrate 11 between the peripheral conductive patterns PG may be exposed by the spacer etching. At the same time, the nitride layer 31A (see FIG. 18A) over the peripheral conductive pattern PG may be etched, but the concept and scope of the present invention are not limited thereto. In an embodiment, the nitride layer 31A over the top surface of the peripheral conductive pattern PG may not be etched.

Therefore, the continuous nitride layer 31B covering the substrate 11 between the core conductive patterns CG may remain in the core region CORE, and offset nitride spacers 31 disposed only on both sidewalls of the peripheral conductive patterns PG may be formed in the peripheral region PERI.

Next, the peripheral open mask 32 may be removed.

Referring to FIG. 18C, a first oxide layer 18A may be formed over the nitride layer 31B of the core region CORE and the peripheral conductive pattern PG of the peripheral region PERI.

Referring to FIG. 18D, a core open mask 33 may be formed over the first oxide layer 18A (refer to FIG. 18C) of the peripheral region PERI.

Next, the core open mask 33 may be removed.

Subsequently, the first oxide layer 18A (see FIG. 18C) of the core region CORE may be removed. The first oxide layer 18B may remain only in the peripheral region PERI.

Referring to FIG. 18E, a second oxide layer 20A may be formed over the nitride layer 31B of the core region CORE and the first oxide layer 18B of the peripheral region PERI.

Referring to FIG. 18F, spacer etching may be performed. As a result of the spacer etching, a peripheral spacer structure PSP where the offset nitride spacers 31, the first oxide spacers 18, and the second oxide spacers 20 are stacked may be formed on both sidewalls of the peripheral conductive patterns PG. Also, a core spacer structure CSP where the buffer nitride spacer 31′ and the second oxide spacer 20 are stacked may be formed on both sidewalls of the core conductive pattern CG.

As described above, according to the embodiment of the present invention, spacer materials having an etch selectivity may be applied to form the spacer structures optimized for the requirements of the peripheral region PERI and the core region CORE, individually. In particular, mismatch of a sense amplifier transistor based on the variation of ion implantation may be reduced by forming the total thickness of the core spacer structure CSP smaller than the total thickness Wp of the peripheral spacer structure PSP.

Also, since a dopant may be directly injected into the substrate 11 by applying the offset nitride spacer 31 remaining only on both sidewalls of the peripheral conductive pattern PG to the peripheral region PERI, it may be advantageous for junction engineering. It is also possible to minimize the loss of the substrate 11 during the spacer etching by applying the first oxide layer as a buffer layer before the second oxide spacer is formed. Accordingly, the characteristics of a Ring Oscillator Delay (ROD), which is a major indicator of the operating speed characteristics of a device, may be improved.

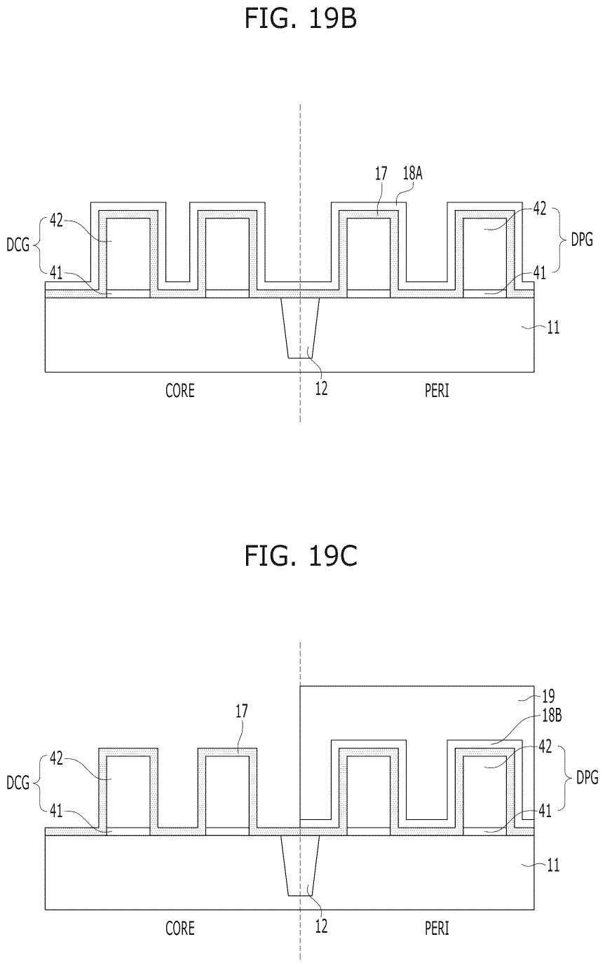

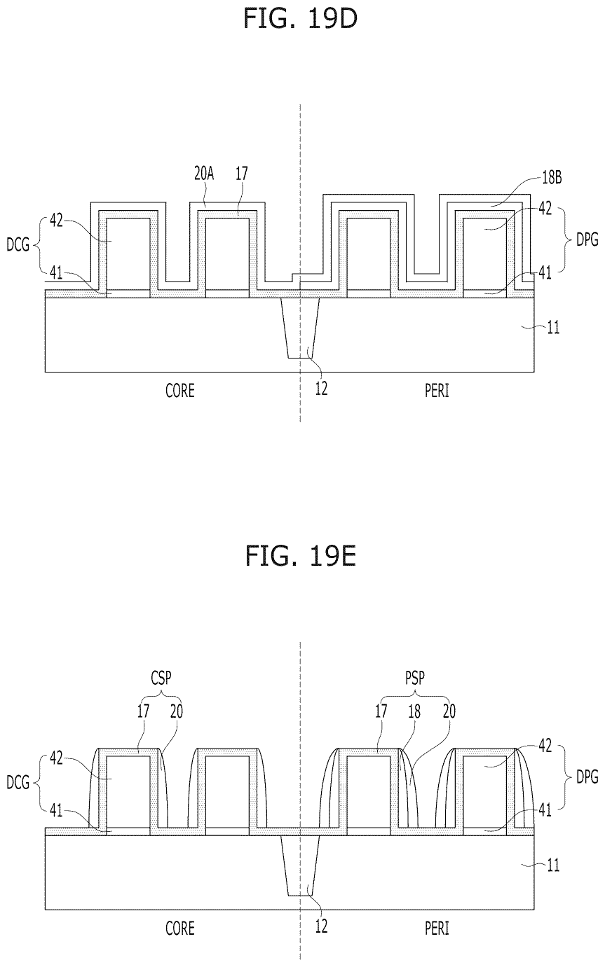

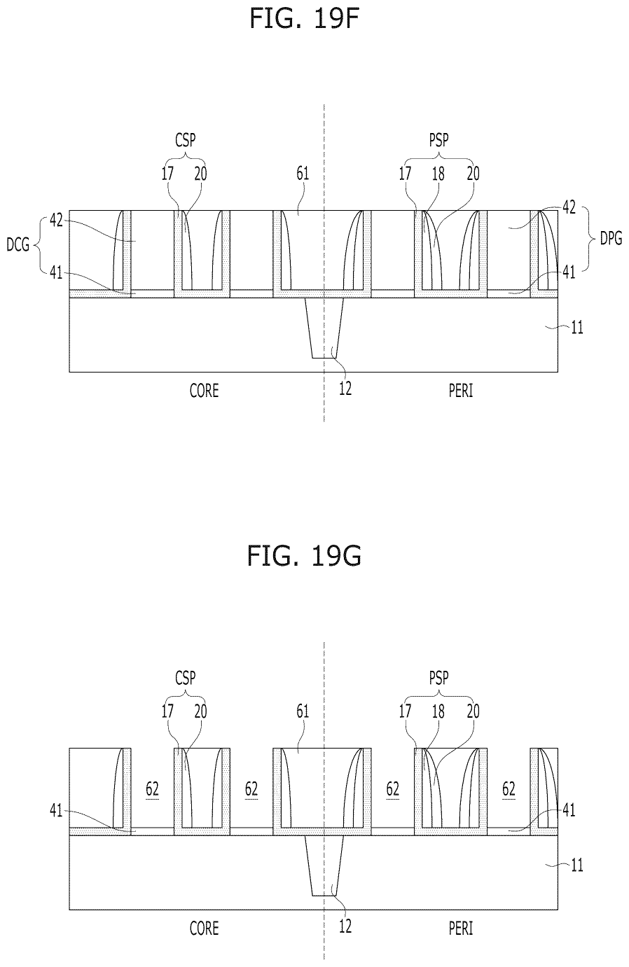

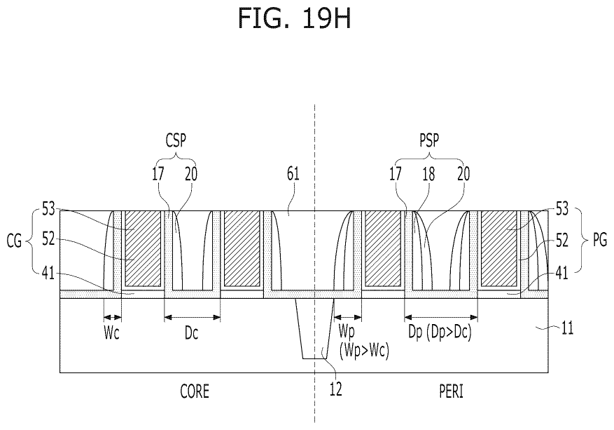

FIGS. 19A to 19H are cross-sectional views illustrating an example of a method for fabricating a semiconductor device including an RMG structure in accordance with an embodiment of the present invention. FIGS. 19A to 19E describe a method for fabricating the semiconductor device shown in FIG. 9, and the process may be the same as the method for fabricating the semiconductor device illustrated in FIGS. 10 to 12, except for the type of the spacer material. Also, the semiconductor device illustrated in FIGS. 13 to 16 may go through the same process as illustrated in FIGS. 18A to 18F to form the spacer structure, except for the stacked structure of the conductive patterns, and go through the same process as illustrated in FIGS. 19F to 19H to apply the RMG structure, except for the spacer structure.

Referring to FIG. 19A, in the substrate 11, the isolation layer 12 may divide the substrate 11 into the peripheral region PERI and the core region CORE and define an active region.

The substrate 11 may be a material suitable for semiconductor processing. The substrate 11 may include a semiconductor substrate. The substrate 11 may be formed of a silicon-containing material. The substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may also include other semiconductor materials, such as germanium. The substrate 11 may include a III/V-group semiconductor substrate, for example, a compound semiconductor substrate, such as GaAs. The substrate 101 may include a Silicon-On-Insulator (SOI) substrate.

Subsequently, a peripheral dummy pattern DPG and a core dummy pattern DCG may be formed over the substrate 11 in the peripheral region PERI and the core region CORE, respectively. The peripheral dummy pattern DPG and the core dummy pattern DCG may include the same stacked structure.

The line widths of the peripheral dummy pattern DPG and the core dummy pattern DCG may be different or the same. For example, in an embodiment, as the core region adjacent to the cell region is reduced due to the miniaturization of the semiconductor devices, the distance Dp between the peripheral dummy patterns DPG may be longer than the distance Dc between the core dummy patterns DCG (Dp>Dc).

The peripheral dummy pattern DPG and the core dummy pattern DCG may include a stacked structure of the same materials. In other words, the peripheral dummy pattern DPG and the core dummy pattern DCG may be simultaneously formed by sequentially stacking the same material layers and patterning them once. The peripheral dummy pattern DPG and the core dummy pattern DCG may be formed as a stacked structure of a gate dielectric layer 41 and a dummy gate electrode 42, individually.

Subsequently, the nitride layer 17 may be formed along the profile of the entire structure including the peripheral dummy pattern DPG and the core dummy pattern DCG.

Referring to FIG. 19B, a first oxide layer 18A may be formed over the nitride layer 17.

Referring to FIG. 19C, a core open mask 19 may be formed over the first oxide layer 18A (refer to FIG. 19B) of the peripheral region PERI. The core open mask 19 may be formed of, for example, a photoresist.

Subsequently, the first oxide layer 18A (see FIG. 19B) of the core region CORE may be removed. The first oxide layer 18B may remain only in the peripheral region PERI.

Referring to FIG. 19D, the core open mask 19 may be removed. Subsequently, a second oxide layer 20A may be formed over the nitride layer 17 of the core region CORE and the first oxide layer 18B of the peripheral region PERI.

Referring to FIG. 19E, spacer etching may be performed. As a result of the spacer etching, a peripheral spacer structure PSP where the buffer nitride spacer 17, a first oxide spacer 18, and a second oxide spacer 20 are stacked may be formed on both sidewalls of the peripheral dummy pattern DPG. Also, a core spacer structure CSP where the buffer nitride spacer 17 and the second oxide spacer 20 are stacked may be formed on both sidewalls of the core dummy pattern DCG.

Referring to FIG. 19F, an inter-layer dielectric layer 61 may be formed to gap-fill the space between the core dummy pattern DCG and the peripheral dummy pattern DPG. The inter-layer dielectric layer 61 may be formed through a series of processes of forming a dielectric material to fill the space between the core dummy pattern DCG and the peripheral dummy pattern DPG, and etching the dielectric material targeting to expose the upper surfaces of the core and peripheral dummy patterns DCG and DPG. The inter-layer dielectric layer 61 may include a material having an etch selectivity with respect to the dummy gate electrode 42. The inter-layer dielectric layer 61 may include, for example, one selected among silicon oxide, silicon nitride, and silicon oxynitride.

Referring to FIG. 19G, the dummy gate electrodes 42 of the core dummy pattern DCG and the peripheral dummy pattern DPG (see FIG. 19F) may be removed. Accordingly, recesses 62 may be formed at the positions of the core dummy pattern DCG (see FIG. 19G) and the peripheral dummy pattern DPG (see FIG. 19G). Herein, the gate dielectric layer 41 may remain on the bottom surface of the recess 62.

Referring to FIG. 19H, a core RMG structure CG and a peripheral RMG structure PG may be formed by gap-filling the recesses 62 of the core region CORE and the peripheral region PERI with the high-k layer 52 and the gate electrode 53, respectively. The upper surfaces of the core RMG structure CG and the peripheral RMG structure PG may be disposed at the same level as the upper surface of the inter-layer dielectric layer 61. To this end, a series of processes of depositing a high-k material along the profile of the entire structure including the recesses of the core region CORE and the peripheral region PERI, forming a conductive material that fills the recesses over the high-k material, and then etching the high-k material and the conductive material targeting the upper surface of the inter-layer dielectric layer 61 may be performed.

The high-k layer 52 may be formed to cover the bottom surface and the inner side surface of the recess 62 (see FIG. 19G). The high-k layer 52 may include a high-k material having a higher dielectric constant than silicon oxide. For example, the high-k layer 52 may include at least one among boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate electrode 53 may include at least one among a metal, a metal alloy, a conductive metal nitride, a metal silicide, a doped semiconductor material, a conductive metal oxide, and a conductive metal oxynitride. The gate electrode 53 may be, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TIAlN), tantalum aluminum nitride (TaAlN), tungsten nitride (WN), ruthenium (Ru), titanium aluminum (TiAl), titanium aluminum carbonitride (TIAlC-N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but the concept and scope of the present invention are not limited thereto. The conductive metal oxide and conductive metal oxynitride may include an oxidized form of the above-described material, but the concept and scope of the present invention are not limited thereto.

As described above, according to the embodiment of the present invention, spacer materials having an etch selectivity may be applied to form the spacer structures optimized for the requirements of the peripheral region PERI and the core region CORE, individually. In particular, mismatch of a sense amplifier transistor based on the variation of ion implantation may be reduced by forming the total thickness Wp of the peripheral spacer structure PSP.

According to the embodiment of the present invention, the thickness of the spacers formed in the core region and the peripheral region may be dualized so that the spacers may have the optimal thickness adjusted for each region.

According to the embodiment of the present invention, semiconductor devices may be secured with reliability by forming spacers to have the optimized thickness in a core region and a peripheral region.

While the present invention has been described with respect to the specific embodiments, it will be apparent to those skilled in the art that various changes and modifications may be made without departing from the concept and scope of the invention as defined in the following claims.

What is claimed is:

1. A semiconductor device, comprising:
a substrate including a peripheral region and a core region;
a first conductive pattern disposed over the substrate of the peripheral region;
a second conductive pattern disposed over the substrate of the core region;
a first spacer structure formed on both sidewalls of the first conductive pattern; and
a second spacer structure having a thickness which is smaller than a total thickness of the first spacer structure formed on both sidewalls of the second conductive pattern.

2. The semiconductor device of claim 1, wherein the first and second spacer structures include buffer spacers.

3. The semiconductor device of claim 1, wherein the first and second spacer structures have different stacked structures.

4. The semiconductor device of claim 1, wherein the first spacer structure includes a stacked structure of a buffer nitride spacer, a first oxide spacer, and a second oxide spacer, and
the second spacer structure includes a stacked structure of the buffer nitride spacer and the second oxide spacer.

5. The semiconductor device of claim 1, wherein the first spacer structure includes a stacked structure of a buffer nitride spacer, a low-k spacer, and an oxide spacer, and
the second spacer structure includes a stacked structure of the buffer nitride spacer and the oxide spacer.

6. The semiconductor device of claim 1, wherein the first spacer structure includes a stacked structure of a buffer first nitride spacer, an oxide spacer, and a second nitride spacer, and
the second spacer structure includes a stacked structure of the buffer first nitride spacer and the second nitride spacer.

7. The semiconductor device of claim 1, wherein the first spacer structure includes a stacked structure of a buffer nitride spacer, an oxide spacer, and a low-k spacer, and
the second spacer structure includes a stacked structure of the buffer nitride spacer and the low-k spacer.

8. The semiconductor device of claim 1, wherein the first spacer structure includes an offset spacer.

9. The semiconductor device of claim 1, wherein the first spacer structure includes a stacked structure of an offset nitride spacer, a first oxide spacer, and a second oxide spacer, and
the second spacer structure includes a stacked structure of a buffer nitride spacer and the second oxide spacer.

10. The semiconductor device of claim 1, wherein the first spacer structure includes a stacked structure of an offset nitride spacer, a low-k spacer, and an oxide spacer, and
the second spacer structure includes a stacked structure of a buffer nitride spacer and the oxide spacer.

11. The semiconductor device of claim 1, wherein the first spacer structure includes a stacked structure of an offset first nitride spacer, an oxide spacer, and a second nitride spacer, and
the second spacer structure includes a stacked structure of a buffer first nitride spacer and a second nitride spacer.

12. The semiconductor device of claim 1, wherein the first spacer structure includes a stacked structure of an offset nitride spacer, an oxide spacer, and a low-k spacer, and
the second spacer structure includes a stacked structure of a buffer nitride spacer and the low-k spacer.

13. The semiconductor device of claim 1, wherein the first and second conductive patterns include planar gate patterns.

14. The semiconductor device of claim 1, wherein the first and second conductive patterns include a replacement metal gate (RMG) structure.
